(19) United States
(12) Patent Application Publication
(10) Pub. No.: US 2026/0240026 A1
(43) Pub. Date: Aug. 13, 2026

(54) AERONAUTICAL PROPULSION SYSTEM

(71) Applicant: SAFRAN AIRCRAFT ENGINES, Paris (FR)

(72) Inventors: Jonathan Jean-Pierre ROUFFET, Moissy-Cramayel (FR); Didier René André ESCURE, Moissy-Cramayel (FR); Maxime Paul Numa GIVERT, Moissy-Cramayel (FR)

(73) Assignee: SAFRAN AIRCRAFT ENGINES, Paris (FR)

(21) Appl. No.: 19/535,253

(22) Filed: Feb. 10, 2026

(30) Foreign Application Priority Data
Feb. 10, 2025 (FR) 2501358

(51) Int. Cl. H10W 72/00

(52) U.S. Cl. CPC H10W 72/0198

(57) ABSTRACT

An aeronautical propulsion system includes a ducted fan section with a fan shaft extending along a longitudinal axis, supported by a first guiding system. A drive shaft to be driven by a turbine and that is supported by a second guiding system includes thrust bearings. A reduction structure, including an epicyclic gear train with a ring gear, couples the drive shaft to the fan shaft such that the drive shaft rotates at a higher speed than the fan shaft. A support attaches the reduction structure to a stator. A coupling device connects the drive shaft to the reduction structure and compensates for misalignment therebetween. The coupling device includes shaft sections and radial flexibility elements connecting the shaft sections. Specific dimensional ratios between axial distances of the guiding systems, reduction structure, support, and coupling device elements relative to a reference plane are defined to optimize system performance.

### TECHNICAL FIELD

This invention relates to the aeronautical field. More precisely, this invention relates to geared aeronautical engines.

### PRIOR ART

Some aeronautical engines have a reduction gear architecture in order to improve their efficiency. However, during the operation of such engines, the reduction gearbox is subjected to mechanical stresses liable to reduce its life. Furthermore, the reduction gearbox has a bulk that adversely affects the compactness of such engines, and hence their fuel consumption.

### SUMMARY

An aim of the present disclosure is to improve the compactness and increase the life of the reduction gear architecture of an aeronautical engine.

For this purpose, provision is made for an aeronautical propulsion system comprising: a stator;
a fan section comprising a fan shaft extending along a longitudinal axis, the fan section being ducted;
a first guiding system supporting and rotationally guiding the fan shaft, the first guiding system comprising a part which is fixed with respect to the stator and an active part configured to transmit a force between the fan shaft and the fixed part;
a drive shaft extending along the longitudinal axis and configured to be driven by a turbine of the aeronautical propulsion system;
a second guiding system supporting and rotationally guiding the drive shaft;
a reduction mechanism coupling the drive shaft to the fan shaft such that a rotation of the drive shaft at a first speed drives a rotation of the fan shaft at a second speed which is less than the first speed;
a support attaching the reduction mechanism to the stator; and
a coupling device connecting the drive shaft to the reduction mechanism and configured to compensate for a misalignment between the drive shaft and the reduction mechanism, the coupling device comprising a plurality of shaft sections and a plurality of radial flexibility elements, each of the plurality of shaft sections extending along the longitudinal axis, each of the plurality of radial flexibility elements connecting two of the plurality of shaft sections to one another and being configured to compensate for a misalignment between the two of the plurality of shaft sections;
wherein the active part of the first guiding system has a first axial end and a second axial end, a reference plane orthogonal to the longitudinal axis being axially positioned at equal distance from the first axial end and from the second axial end of the active part of the first guiding system;
wherein the second guiding system comprises a plurality of thrust bearings, a first thrust bearing of the plurality of thrust bearings being axially positioned nearer to the reduction mechanism than the others of the plurality of thrust bearings, the first thrust bearing comprising a part which is fixed with respect to the stator and an active part configured to transmit a force between the drive shaft and the fixed part, the active part of the first thrust bearing having a first axial end and a second axial end, a first plane orthogonal to the longitudinal axis being axially positioned at equal distance from the first axial end and from the second axial end of the active part of the first thrust bearing, the first plane being further axially positioned at a first distance from the reference plane;
wherein the support has a first end connected to the stator and a second end connected to the reduction mechanism, the first end of the support being axially positioned at a second distance from the reference plane and the second end of the support being axially positioned at a third distance from the reference plane;
wherein the reduction mechanism is an epicyclic gear train comprising a ring gear having a first axial end and a second axial end, a second plane orthogonal to the longitudinal axis being axially positioned at equal distance from the first axial end and from the second axial end of the ring gear, the second plane being further axially positioned at a fourth distance from the reference plane;
wherein the first guiding system comprises a plurality of rolling elements aligned in a third plane orthogonal to the longitudinal axis, the third plane being axially positioned between the reference plane and the reduction mechanism, the third plane being further axially positioned at a fifth distance from the reference plane;
wherein a first radial flexibility element of the plurality of radial flexibility elements of the coupling device is positioned nearer to the first guiding system than the others of the plurality of radial flexibility elements, the first radial flexibility element comprising a first axial end and a second axial end, a fourth plane orthogonal to the longitudinal axis being axially positioned at equal distance from the first axial end and from the second axial end of the first radial flexibility element, the fourth plane being further axially positioned at a sixth distance from the reference plane;
wherein a second radial flexibility element of the plurality of radial flexibility elements of the coupling device is positioned nearer to the second guiding system than the others of the plurality of radial flexibility elements, the second radial flexibility element having a first axial end and a second axial end, a fifth plane orthogonal to the longitudinal axis being axially positioned at equal distance from the first axial end and from the second axial end of the second radial flexibility element, the fifth plane being further axially positioned at a seventh axial distance from the reference plane;
wherein a ratio of the second distance to the first distance is greater than or equal to 0.1, preferably greater than or equal to 0.255, and less than or equal to 0.55, preferably less than or equal to 0.395;
wherein a ratio of the third distance to the first distance is greater than or equal to 0.6 and less than or equal to 0.85;
wherein a ratio of the fourth distance to the first distance is greater than or equal to 0.25, preferably greater than or equal to 0.4, and less than or equal to 0.55, preferably less than or equal to 0.49;
wherein a ratio of the fifth distance to the first distance is greater than or equal to 0.1, preferably greater than or equal to 0.2, and less than or equal to 0.39, preferably less than or equal to 0.3;
wherein a ratio of the sixth distance to the first distance is greater than or equal to 0.54, preferably greater than or equal to 0.6, and less than or equal to 0.75, preferably less than or equal to 0.65;
wherein a ratio of the seventh distance to the first distance is greater than or equal to 0.6, preferably greater than or equal to 0.75, and less than or equal to 0.95, preferably less than or equal to 0.85;
wherein a ratio of, on the one hand, a difference between the seventh distance and the sixth distance to, on the other hand, the first distance, is greater than or equal to 0.09, preferably greater than or equal to 0.11, and less than or equal to 0.2, preferably less than or equal to 0.18; and
wherein a ratio of, on the one hand, a difference between the seventh distance and the fourth distance to, on the other hand, the fourth distance, is greater than or equal to 0.6, preferably greater than or equal to 0.9, and less than or equal to 1.2, preferably less than or equal to 1.1.

The first radial flexibility element can further be axially positioned between the reduction mechanism and the second guiding system.

According to another aspect of the present disclosure, provision is made for an aircraft comprising an airframe and an aeronautical propulsion system according to the present disclosure, wherein the aeronautical propulsion system is attached to the airframe.

According to another aspect of the present disclosure, provision is made for a method for manufacturing an aircraft comprising:
a fan section comprising a fan shaft extending along a longitudinal axis, the fan shaft being ducted;
a first guiding system supporting and rotationally guiding the fan shaft, the first guiding system comprising a part which is fixed with respect to the stator and an active part configured to transmit a force between the fan shaft and the fixed part;
a drive shaft extending along the longitudinal axis and configured to be driven by a turbine a stator;
of the aeronautical propulsion system;
a second guiding system supporting and rotationally guiding the drive shaft;
a reduction mechanism coupling the drive shaft to the fan shaft such that a rotation of the drive shaft at a first speed drives a rotation of the fan shaft at a second speed which is less than the first speed;
a support attaching the reduction mechanism to the stator; and
a coupling device connecting the drive shaft to the reduction mechanism and configured to compensate for a misalignment between the drive shaft and the reduction mechanism, the coupling device comprising a plurality of shaft sections and a plurality of radial flexibility elements, each of the plurality of shaft sections extending along the longitudinal axis, each of the plurality of radial flexibility elements connecting two of the plurality of shaft sections to one another and being configured to compensate for a misalignment between the two of the plurality of shaft sections;
wherein the active part of the first guiding system has a first axial end and a second axial end, a reference plane orthogonal to the longitudinal axis being axially positioned at equal distance from the first axial end and from the second axial end of the active part of the first guiding system;
wherein the second guiding system comprises a plurality of thrust bearings, a first thrust bearing of the plurality of thrust bearings being axially positioned nearer to the reduction mechanism than the others of the plurality of thrust bearings, the first thrust bearing comprising a part which is fixed with respect to the stator and an active part configured to transmit a force between the drive shaft and the fixed part, the active part of the first thrust bearing having a first axial end and a second axial end, a first plane orthogonal to the longitudinal axis being axially positioned at equal distance from the first axial end and from the second axial end of the active part of the first thrust bearing, the first plane being further axially positioned at a first distance from the reference plane;
wherein the support has a first end connected to the stator and a second end connected to the reduction mechanism, the first end of the support being axially positioned at a second distance from the reference plane and the second end of the support being axially positioned at a third distance from the reference plane;
wherein the reduction mechanism is an epicyclic gear train comprising a ring gear having a first axial end and a second axial end, a second plane orthogonal to the longitudinal axis being axially positioned at equal distance from the first axial end and from the second axial end of the ring gear, the second plane being further axially positioned at a fourth distance from the reference plane;
wherein the first guiding system comprises a plurality of rolling elements aligned in a third plane orthogonal to the longitudinal axis, the third plane being axially positioned between the reference plane and the reduction mechanism, the third plane being further axially positioned at a fifth distance from the reference plane;
wherein a first radial flexibility element of the plurality of radial flexibility elements of the coupling device is positioned nearer to the first guiding system than the others of the plurality of radial flexibility elements, the first radial flexibility element comprising a first axial end and a second axial end, a fourth plane orthogonal to the longitudinal axis being axially positioned at equal distance from the first axial end and from the second axial end of the first radial flexibility element, the fourth plane being further axially positioned at a sixth distance from the reference plane;
wherein a second radial flexibility element of the plurality of radial flexibility elements of the coupling device is positioned nearer to the second guiding system than the others of the plurality of radial flexibility elements, the second radial flexibility element having a first axial end and a second axial end, a fifth plane orthogonal to the longitudinal axis being axially positioned at equal distance from the first axial end and from the second axial end of the second radial flexibility element, the fifth plane being further axially positioned at a seventh axial distance from the reference plane;
wherein the manufacturing method comprises a dimensioning of the aeronautical propulsion system during which:
   a ratio of the second distance to the first distance is determined greater than or equal to 0.1, preferably greater than or equal to 0.255, and less than or equal to 0.55, preferably less than or equal to 0.395;
      a ratio of the third distance to the first distance is determined greater than or equal to 0.6 and less than or equal to 0.85;
      a ratio of the fourth distance to the first distance is determined greater than or equal to 0.25, preferably greater than or equal to 0.4, and less than or equal to 0.55, preferably less than or equal to 0.49;
      a ratio of the fifth distance to the first distance is determined greater than or equal to 0.1, preferably greater than or equal to 0.2, and less than or equal to 0.39, preferably less than or equal to 0.3;
      a ratio of the sixth distance to the first distance is determined greater than or equal to 0.54, preferably greater than or equal to 0.6, and less than or equal to 0.75, preferably less than or equal to 0.65;
      a ratio of the seventh distance to the first distance is determined greater than or equal to 0.6, preferably greater than or equal to 0.75, and less than or equal to 0.95, preferably less than or equal to 0.85; and
      a ratio of, on the one hand, a difference between the seventh distance and the sixth distance to, on the other hand, the first distance is determined greater than or equal to 0.09, preferably greater than or equal to 0.11, and less than or equal to 0.2, preferably less than or equal to 0.18; and
   a ratio of, on the one hand, a difference between the seventh distance and the fourth distance to, on the other hand, the fourth distance, is determined greater than or equal to 0.6, preferably greater than or equal to 0.9, and less than or equal to 1.2, preferably less than or equal to 1.1.

### DESCRIPTION OF THE FIGURES

FIG. 1 illustrates an example of an aircraft which may comprise a propulsion system.

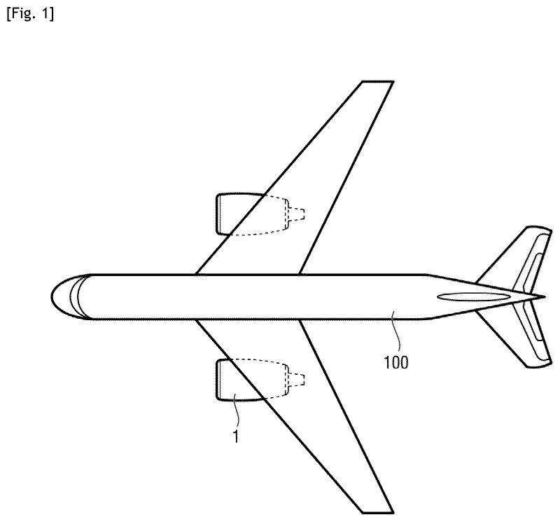

FIG. 2 is a schematic, partial and section view of an example of a propulsion system wherein the fan section is ducted.

FIG. 3 is a schematic, partial and section view of an example of a propulsion system wherein the fan section is unducted.

FIG. 4 is a schematic section view of an example of a star reduction mechanism.

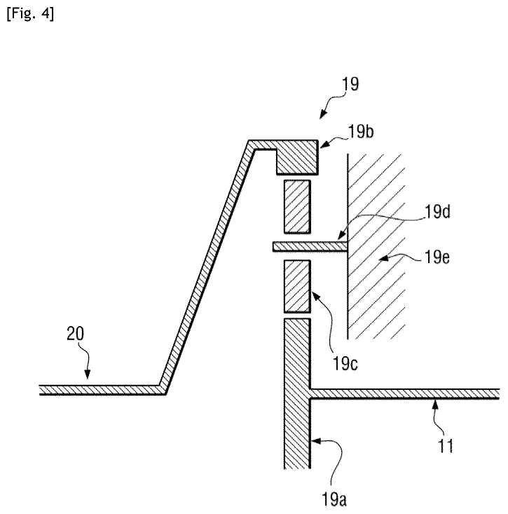

FIG. 5 is a schematic section view of an example of a planetary reduction mechanism.

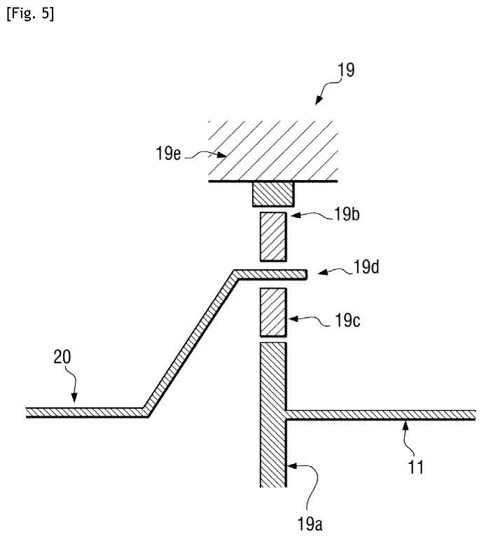

FIG. 6 is a schematic section view of an example of a star reduction gear architecture.

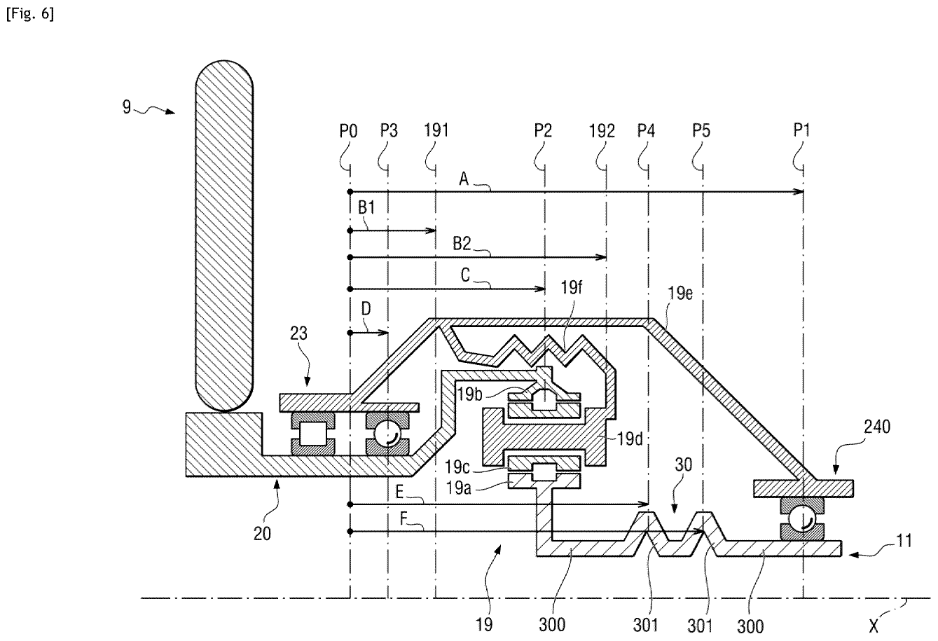

FIG. 7 is a schematic section view of an example of a planetary reduction gear architecture.

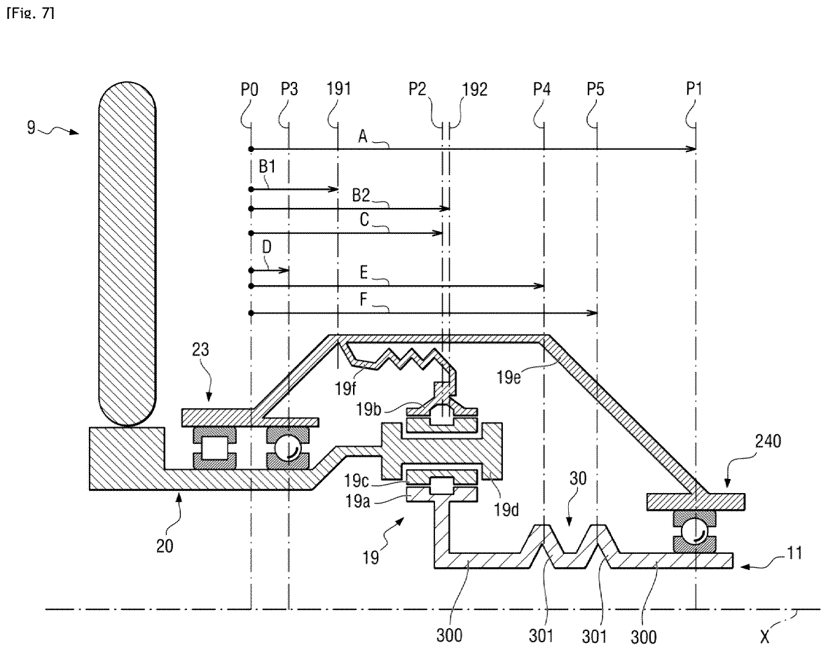

FIG. 8 is a schematic section view of another example of a planetary reduction gear architecture.

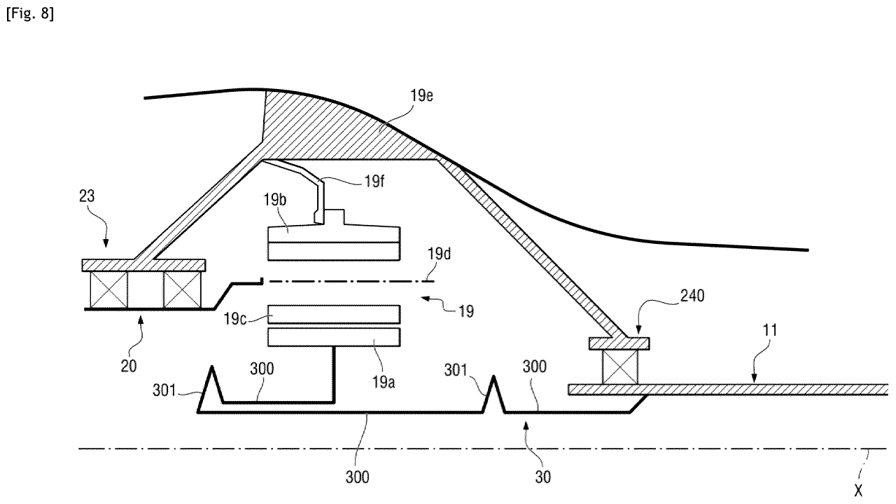

### DETAILED DESCRIPTION

### Aircraft

An aircraft 100 is an apparatus configured to rise up and move through the air, and may, for example, be an airplane, civil or military, or even a helicopter. An aircraft 100 comprises an airframe which, in the case of an airplane, is composed of a fuselage, of a set of airfoils comprising two wings, of stabilizers, of control surfaces and of a landing gear.

### Propulsion System

A propulsion system 1 has a main direction along a longitudinal axis X along which the propulsion system 1 extends.

The propulsion system 1 is an aeronautical propulsion system 1 configured to be attached to the airframe of the aircraft 100 by way of a pylon (or mast), which is attached to the airframe of the aircraft.

The propulsion system 1 is configured to supply a thrust greater than or equal to 18 000 lbf (80 068 N), preferably greater than or equal to 20 000 lbf (88 964 N), and less than or equal to 51 000 lbf (226 859 N), preferably less than or equal to 35 000 lbf (155 688 N).

In the present disclosure, an axial direction corresponds to the direction of the longitudinal axis X, and a radial direction is a direction perpendicular to the longitudinal axis X and passing through it. Further, a circumferential (or lateral, or tangential) direction corresponds to a direction perpendicular to the longitudinal axis X and not passing through it. Unless otherwise specified, inner (or respectively, inward) and outer (or respectively, outward), are used with reference to a radial direction such that the inner part or face of an element is nearer to the longitudinal axis X than the outer part or face of the same element.

In the present disclosure, the operating parameters of the propulsion system 1 (pressure, flow rate, thrust, speed, etc.) are measured when the propulsion system 1 is stationary, uninstalled, in takeoff rating in a standard atmosphere (as defined by the International Civil Aviation Organization Handbook, Doc 7488/3, 3rd edition) and at sea level. The term “uninstalled” means that the measurements are taken when the propulsion system 1 is on a test bench (and not installed on an aircraft 100), the measurements then being easier to take.

In the present disclosure, the distances, or dimensions (length, width, radius, diameter, etc.), of the propulsion system 1 are measured at ambient temperature (approximately 20° C.) when the propulsion system 1 is cool, i.e. when the propulsion system 1 has been shut down for long enough for the parts of the propulsion system 1 to be at ambient temperature, it being understood that these dimensions vary little in relation to the conditions under which the propulsion system 1 is in the takeoff rating.

The propulsion system 1 comprises, from upstream to downstream in the direction of flow of the gas through the propulsion system 1 when it is in operation, a fan section 2 and a primary spool 3, often known as the “gas generator”, centered on the longitudinal axis X and comprising a compressor section 4, 5, a combustion chamber 6 and a turbine section 7, 8.

In operation, an air stream F entering the propulsion system 1 is divided into a primary air stream F1 and a secondary air stream F2, which circulate from upstream to downstream through the propulsion system 1.

The secondary air stream F2, also known as “bypass air stream”, flows around the primary spool 3. The secondary air stream F2 is used to cool the periphery of the primary spool 3 and serves to generate the majority of the thrust supplied by the propulsion system 1.

The primary are stream F1 flows through a primary air path 29 inside the primary spool 3, passing successively through the compressor section 4, 5, the combustion chamber 6 where it is mixed with fuel to act as comburent, and the turbine section 7, 8.

A bypass ratio of the propulsion system 1 is defined as a ratio of the mass flow rate of the secondary air stream F2 to the mass flow rate of the primary air stream F1.

The fan section 2 comprises at least one rotor 9 suitable for being rotationally driven, by the primary spool 3, about the longitudinal axis X, with respect to a stator part 19e of the propulsion system 1. In this way, the air stream F is suctioned to enter the propulsion system 1. The rotor 9 comprises a hub 13 and blades 14 extending radially from the hub 13 all the way to a tip 21, and having a leading edge 22 which the air stream F strikes first when it makes contact with the blades 14. The blades 14 may be fixed with respect to the hub 13 or have a variable pitch angle. In this case, the root of each blade 14 is mounted pivotably along a pitch axis and is connected to a pitch change mechanism 15 mounted in the propulsion system 1, the pitch angle being adjusted as a function of the flight phase by the pitch change mechanism. The rotor 9 comprises at least fourteen blades 14 and at the most twenty-four blades 14, preferably at least sixteen blades 14 and at the most twenty-two blades 14.

The fan section 2 may further comprise a stator 16, or straightener, which comprises blades 17 mounted on a hub of the stator 16 and which have the function of straightening the secondary air stream F2 which flows through the outlet of the rotor 9. The blades 17 may be fixed with respect to the hub of the stator 16 or have a variable pitch angle. Where applicable, and similarly to the blades 14 of the rotor 9, the root of each stator 16 blade 17 is mounted pivotably along a pitch axis and is connected to a pitch change mechanism 15a, which is generally distinct from that of the rotor 9, the pitch angle being adjusted as a function of the flight phase by the pitch change mechanism 15a. The number of blades in the stator 16 depends on the acoustic criteria defined for the propulsion system 1 and is at least equal to the number of blades 14 in the rotor 9.

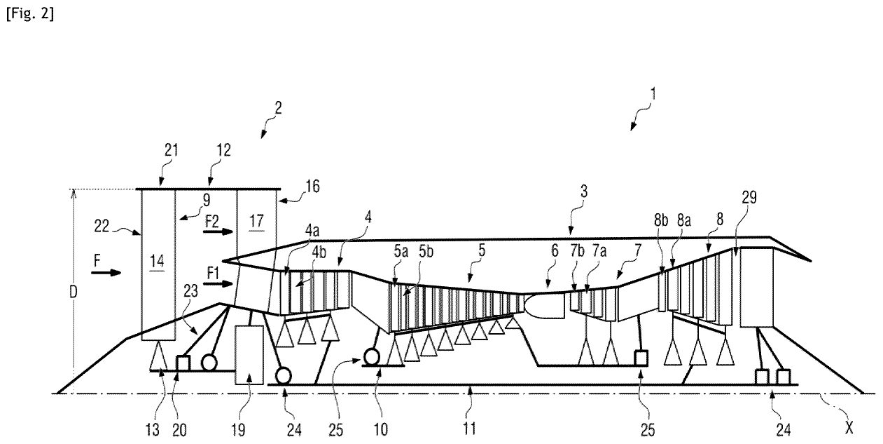

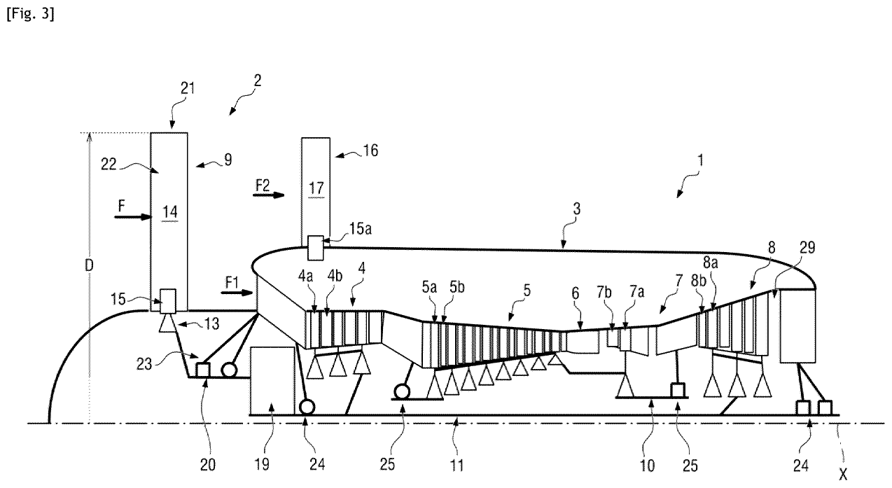

The compression ratio of the fan section 2 is defined as the ratio of the average pressure at the outlet of the stator 16 (or, if there is no stator 16, of the rotor 9) to the average pressure at the inlet of the rotor 9, in the direction of flow of the air stream F when the propulsion system 1 is in operation. Here the average pressures are measured over the height of at least one of the blades 14 of the rotor 9, i.e. from the surface that inwardly radially delimits the air flow path at the inlet of the rotor 9 up to the tip 21 of the blade 14. In a propulsion system 1 with a high bypass ratio, most of the flow generating the propulsive force is formed by the secondary air stream F2 of the propulsion system 1, the kinetic energy of the secondary air stream F2 being mostly affected by the compression undergone by the secondary air stream F2 on crossing the fan section 2. The propulsive efficiency and the compression ratio of the fan section 2 are therefore related:the lower the compression ratio of the fan section 2, the better the propulsive efficiency. In order to optimize the propulsive efficiency of the propulsion system 1, the compression ratio of the fan section 2 is less than or equal to 1.70, preferably less than or equal to 1.50, for example between 0.90 and 1.45. The diameter D of the rotor 9 is measured in a plane normal to the axis of rotation of the rotor 9, at an intersection between the tip 21 and the leading edge 22 of the blades 14 of the rotor 9. Note that, since FIG. 2 and FIG. 3 are partial views, the diameter D is only partially visible.

The fan section 2 may be ducted or unducted.

In the case of a ducted fan section 2, the fan section 2 comprises a fan casing 12 and the rotor 9 is housed in the fan casing 12. A ducted fan section 2 comprises a rotor 9 extending upstream of a stator 16. The blades 17 of the stator 16 are then generally referred to as OGV (Outlet Guide Vanes) and have a fixed pitch with respect to the hub of the stator 16. Moreover, the bypass ratio of the propulsion system 1 is preferably greater than or equal to 10, for example between 10 and 35 inclusive, preferably between 10 and 18 inclusive, which improves the propulsive efficiency of the propulsion system 1 and reduces its specific fuel consumption as well as the noise emitted by the fan section 2. The peripheral speed at the tip 21 of each of the blades 14 of the rotor 9 can moreover be greater than or equal to 260 m·s⁻¹ and less than or equal to 400 m·s⁻¹. The compression ratio of the fan can then be between 1.20 and 1.45. The diameter D of the rotor 9 is preferably between 85 inches (215.9 cm) and 120 inches (304.8 cm) inclusive, for example around 90 inches (228.6 cm), which allows the integration of the propulsion system 1 in a conventional manner, in particular under a wing of the airframe of an aircraft 1.

In an unducted fan section 2, the fan section 2, which can also be denoted by the term “propeller”, is not surrounded by a fan casing. Moreover, the blades 14 of the rotor 9 have a variable pitch angle. Propulsion systems comprising at least one unducted rotor 9 are known by the terms “open rotor” or “unducted fan”. The propulsion system 1 may comprise two unducted and contra-rotating rotors 9. Such a propulsion system 1 is known by the acronym “CROR” for “Contra-Rotating Open Rotor” or “UDF” for “Unducted Double Fan”. The rotors 9 may be placed aft of the primary spool 3 so as to be of push type or forward of the primary spool 3 so as to be of pull type. In a variant, the propulsion system 1 may comprise a single unducted rotor 9 and an unducted stator 16. Such a propulsion system 1 is known by the acronym “USF” for “Unducted Single Fan”. In the case of a propulsion system 1 of USF type, the blades 17 of the stator 16 are rotationally fixed with respect to the longitudinal axis X, which is the axis of rotation of the rotor 9 and, consequently, do not undergo any centrifugal force. The blades 17 of the stator 16 further have a variable pitch angle. The elimination of the duct around the fan section 2 makes it possible to increase the bypass ratio very significantly without the propulsion system 1 being penalized by the mass of the casings 12 or nacelles intended to surround the fan section 2. The bypass ratio of the propulsion system 1 comprising an unducted fan section 2 is thus greater than or equal to 40, for example between 40 and 80 inclusive, which improves the propulsive efficiency of the propulsion system 1 and reduces its specific fuel consumption as well as the noise emitted by the fan section 2. The peripheral speed at the tip 21 of each of the blades 14 of the rotor(s) 9 can further be greater than or equal to 210 m·s⁻¹ and less than or equal to 260 m·s⁻¹. The fan compression ratio can then be preferably between 0.90 and 1.20 inclusive.

The diameter D of the rotor 9 is preferably greater than or equal to 100 inches (254 cm), for example between 120 inches (304.8 cm) and 156 inches (396.2 cm).

The compressor section 4, 5 comprises a series of stages each comprising a wheel of movable blades (rotor) 4a, 5a rotating in front of a wheel of fixed blades (stator) 4b, 5b. The turbine section 7, 8 also comprises a series of stages each comprising a wheel of fixed blades (stator) 7b, 8b behind which rotates a wheel of movable blades (rotor) 7a, 8a.

In a twin-spool propulsion system 1, the compressor section 4, 5 comprises a low-pressure compressor 4 and a high-pressure compressor 5. Moreover, the turbine section 7, 8 comprises a high-pressure turbine 7 and a low-pressure turbine 8. The passage of the primary air stream F1 through the turbine section 7, 8 receiving energy from the combustion chamber 6 causes a rotation of the rotor stages 7a, 8a of the turbine section 7, 8, which in turn rotationally drives the rotor stages 4a, 5a of the compressor section 4, 5 as well as the rotor 9 of the fan section 2. The rotor stages 5a of the high-pressure compressor 5 are rotationally driven by the rotor stages 7a of the high-pressure turbine 7 by way of a high-pressure shaft 10. The rotor stages 4a of the low-pressure compressor 4 and the rotor 9 of the fan section 2 are rotationally driven by the rotor stages 8a of the low-pressure turbine 8 by way of a low-pressure shaft 11. Thus, the primary spool 3 comprises a high-pressure spool comprising the high-pressure compressor 5, the high-pressure turbine 7 and the high-pressure shaft 10, and a low-pressure spool comprising the fan section 2, the low-pressure compressor 4, the low-pressure turbine 8 and the low-pressure shaft 11. The rotation speed of the high-pressure spool is greater than the rotation speed of the low-pressure spool. The twin-spool propulsion system 1 may in particular comprise a high-pressure turbine 7 which is single-stage, i.e. comprising exactly one stage, or two-stage, i.e. comprising exactly two stages, a high-pressure compressor 5 comprising at least eight stages and at the most eleven stages, a low-pressure turbine 8 comprising at least three stages and at the most seven stages and a low-pressure compressor 4 comprising at least two stages and at the most four stages.

In a triple-spool propulsion system 1, the turbine section 7, 8 further comprises an intermediate turbine, positioned between the high-pressure turbine 7 and the low-pressure turbine 8 and the rotor stages of which are configured to drive the rotor stages of the low-pressure compressor 4 by way of an intermediate shaft. The rotor 9 of the fan section 2 and the rotor stages of the high-pressure compressor 5 remain driven by the low-pressure shaft 11 and the high-pressure shaft 10, respectively.

The low-pressure shaft 11 is generally housed, over a segment of its length, in the high-pressure shaft 10 and is coaxial with the high-pressure shaft 10. The low-pressure shaft 11 and the high-pressure shaft 10 may be co-rotating, i.e. be driven in the same direction about the longitudinal axis X. In a variant, the low-pressure shaft 11 and the high-pressure shaft 10 are contra-rotating, i.e. they are driven in opposite directions about the longitudinal axis X. Whatever the scenario, the high-pressure shaft 10 and the low-pressure shaft 11 each extend along the longitudinal axis X. When applicable, the intermediate shaft is housed between the high-pressure shaft 10 and the low-pressure shaft 11. The intermediate shaft and the low-pressure shaft 11 may be co-rotating or contra-rotating.

The redline speed ω of the low-pressure shaft 11, which corresponds to the absolute maximum speed liable to be encountered by the low-pressure shaft 11, and therefore by the rotor stages 4a, 8a of the low-pressure spool, during the entire flight (according to the European certification regulation EASA CS-E 740 or according to the American certification regulation 14-CFR Part 33.87), is greater than or equal to 2 000 revolutions per minute (209 radians per second), for example greater than or equal to 8 500 revolutions per minute (890 radians per second), preferably greater than or equal to 9 000 revolutions per minute (942 radians per second), and less than or equal to 30 000 revolutions per minute (3 142 radians per second), for example less than or equal to 12 000 revolutions per minute (1 267 radians per second), preferably less than or equal to 11 000 revolutions per minute inclusive (1 152 radians per second). The redline speed corresponds to the maximum rotation speed when the propulsion system 1 is healthy, i.e. not at its end of life. It is therefore liable to be achieved by the low-pressure shaft 11 under flight conditions. This redline speed is part of the data declared in the engine type certificate data sheet. Specifically, this rotation speed is usually used as the reference speed for the dimensioning of propulsion systems and in certain certification tests, such as blade loss or rotor integrity tests. Of course, the high-pressure shaft 10, and therefore the rotor stages 5a, 7a of the high-pressure spool, also has a redline speed, defined in the same way as for the low-pressure shaft 11, but greater than that of the low-pressure shaft 11, for example greater than or equal to 8 000 revolutions per minute (838 radians per second) and less than or equal to 30 000 revolutions per minute inclusive (3 142 radians per second). Similarly, the rotor 9 of the fan section 2 also has a redline speed, defined in the same way as for the low-pressure shaft 11, for example greater than or equal to 800 revolutions per minute (84 radians per second) and less than or equal to 6 000 revolutions per minute (628 radians per second).

The rotor 9 of the fan section 2 is uncoupled from the low-pressure shaft 11 using a reduction mechanism 19, placed between an upstream end of the low-pressure shaft 11 and the rotor 9, in order to independently optimize their respective rotation speeds. The reduction mechanism is centered on the longitudinal axis X. In this case, the propulsion system 1 further comprises an additional shaft (or fan shaft 20), the axis of rotation of which is colinear with the longitudinal axis X. The low-pressure shaft 11 connects the rotor stages 9a of the low-pressure turbine 8 to an input of the reduction mechanism 19 while the fan shaft 20 connects the outlet of the reduction mechanism 19 to the rotor 9 of the fan section 2. The rotor 9 of the fan section 2 is driven by the low-pressure shaft 11 through the reduction mechanism 19 and the fan shaft 20 at a rotation speed less than the rotation speed of the low-pressure turbine 8. This uncoupling makes it possible to reduce the rotation speed and the compression ratio of the rotor 9 of the fan section 2 and increase the power extracted by the low-pressure turbine 8. Indeed, the overall efficiency of the propulsion systems is first-order conditional on the propulsive efficiency, which is favorably affected by a minimization of the variation in kinetic energy of the air as it crosses the propulsion system 1.

The reduction mechanism 19 may comprise a planetary or star reduction mechanism, single-stage or two-stage.

For example, the reduction mechanism 19 may be of star type and comprise a sun gear 19a (input of the reduction mechanism 19), centered on an axis of rotation of the reduction mechanism 19 generally colinear with the longitudinal axis X and configured to be rotationally driven by the low-pressure shaft 11, a ring gear 19b (output of the reduction mechanism 19) coaxial with the sun gear 19a and configured to rotationally drive the fan shaft 20 about its axis of rotation, generally colinear with the longitudinal axis X, and a series of planet gears 19c circumferentially distributed around the axis of rotation of the rotor 9 of the fan section 2, between the sun gear 10a and the ring gear 19b, each planet gear 19c being meshed internally with the sun gear 19a and externally with the ring gear 19b. The series of planet gears 19c is mounted on a planet-carrier 19d which is fixed with respect to the stator part 19e of the propulsion system 1, for example with respect to an input casing of the primary spool 3, typically by being connected to it by a dedicated support 19f.

In a variant, the reduction mechanism 19 may be planetary, in which case the ring gear 19b is mounted in a fixed manner on the stator part 19e of the propulsion system 1, typically by being connected to it by means of a dedicated support 19f, and the fan shaft 20 is rotationally driven by the planet carrier 19d.

Whatever the configuration of the reduction mechanism 19, the diameter of the ring gear 19b and of the planet carrier 19d are greater than the diameter of the sun gear 19a, so that the rotation speed of the rotor 9 of the fan section 2 is less than the rotation speed of the low-pressure shaft 11. The reduction ratio of the reduction mechanism 19 is greater than or equal to 2.5 and less than or equal to 11. In the case of a propulsion system 1 comprising a fan section 2 rotor 9 which is ducted, the reduction ratio may be greater than or equal to 2.7 and less than or equal to 3.5, typically around 3.0. In the case of a propulsion system 1 comprising a fan section 2 rotor 9 which is unducted, the reduction ratio may be between 9.0 and 11.0.

The stator 16 of the fan section, the stator stages 4b, 5b of the compressor section 4, 5, the stator stages 7b, 8b of the turbine section 7, 8 and the stator part 19e of the propulsion system 1 are fixed with respect to one another and with respect to the mast making it possible to attach the propulsion system 1 to the airframe of the aircraft 100.

Each of the fan shaft 20, the low-pressure shaft 11 and the high-pressure shaft 10 is supported and rotationally guided, with respect to the stator part 19e of the propulsion system 1 and about the longitudinal axis X, by means of a respective guiding system 23, 24, 25.

Each of the guiding systems 23, 24 comprises, in this regard, a plurality of bearings, each of which may be a plain bearing, a rolling-element bearing, a fluid bearing, or even a magnetic bearing. One bearing of the plurality of bearings may, by the way, be of the same type, or of a different type, than the other bearings of the plurality of bearings. Whatever its type, each bearing comprises at least one active element which transmits the forces between the fixed part and the rotating part of the bearing. In a rolling-element bearing, for example, these are the rolling elements. The rolling-element bearings may have balls or rollers, single or multiple In the case of multiple roller bearings, typically double, the rolling elements are distributed into several groups, typically two, each group of rolling elements being aligned in a plane, the plans being offset from one another along the rolling axis of the bearing, in this case the longitudinal axis X.

Among the plurality of bearings of each of the guiding systems 23, 24 of the low-pressure shaft 11 and of the high-pressure shaft 10, there is a plurality of thrust bearings, a first of which supports and rotationally guides a first axial end of the low-pressure shaft 11 and of the high-pressure shaft 10, respectively, and a second of which supports and rotationally guides a second axial end of the low-pressure shaft 11 and of the high-pressure shaft 10. The first thrust bearing and the second thrust bearing predominantly take up the axial forces, i.e. the forces along the axis of rotation of the bearing, exerted by the low-pressure shaft 11 and the high-pressure shaft 10, respectively, on the stator part 19e of the propulsion system 1. The thrust bearings may be ball bearings, bearing with rollers oriented along a direction non-parallel to the axis of rotation of the bearing, fluid bearings, or magnetic bearings. Whatever the case, bearings with rollers oriented along a direction parallel to the axis of rotation of the bearing cannot take up axial forces and are therefore not thrust bearings. It may however arise that, for reasons of overall stability, the guiding system 24 25 comprises a bearing with rollers oriented along a direction parallel to the longitudinal axis X and which is axially positioned nearer to an axial end of the low-pressure shaft 11, or of the high-pressure shaft 10, than the corresponding thrust bearing.

### Integration of the Reduction Mechanism

The integration of the reduction mechanism 19 axially between the fan shaft 20 and the low-pressure shaft 11 is critical. Specifically, it is advisable to limit its bulk and mass as much as possible, to reduce its impact on the consumption of the propulsion system 1, while controlling its vibrational environment, to ensure it has an acceptable life and/or reduce the frequency of maintenance. However, these limitations are hard to reconcile. Specifically, the limitation of the bulk and of the mass of the environment surrounding the reduction mechanism 19 is liable to cause a deterioration of its vibrational resistance. Conversely, the stiffening of the environment surrounding the reduction mechanism 19 improves its vibrational resistance, but increases its bulk and its mass. Whatever the case the integration of the reduction mechanism 19 into the propulsion system 1 is constrained by the design of the systems surrounding it, typically the shape of the primary air flow path 29, the structure of the fan section 2, and/or the configuration of the guiding system 24 of the low-pressure shaft 11.

In this regard, a coupling device 30 connects the low-pressure shaft 11 to the reduction mechanism 19, rather than the low-pressure shaft 11 being directly coupled to the reduction mechanism 19. Thus, when the reduction mechanism 19 is of star or planetary type, it is the coupling device 30 that drives the sun gear 19a. The aim of the coupling device 30 is to contribute a certain amount of flexibility in the vibrational behavior of the reduction mechanism 19. Hence, the coupling device 30 is configured to compensate for a misalignment between the low-pressure shaft 11 and the reduction mechanism 19, particularly since the reduction mechanism 19 has a vibrational behavior aligned with that of the fan shaft 20. In this way, the vibrational resistance of the reduction mechanism 19 is improved without having to stiffen its environment, and therefore without having to increase the mass and bulk of the propulsion system 1. Various structures of coupling device 30 may be envisioned in this regard, among which are a coupling device 30 generally taking the form of a shaft extending along the longitudinal axis X, but having a certain amount of radial flexibility. In a variant, the coupling device 30 comprises a plurality of shaft sections 300 and a plurality of radial flexibility elements 301. Each of the plurality of shaft sections 300 extends along the longitudinal axis X, a first of the plurality of shaft sections 300 being connected to the low-pressure shaft 11, while a last of the plurality of shaft sections 300 is connected to the reduction mechanism 19, typically to the sun gear 19a. Moreover, each of the plurality of radial flexibility elements 301 connects two of the plurality of shaft sections 300 to one another while being configured to compensate for a misalignment between the two of the plurality of shaft sections 300. Different radial flexibility elements 301 may be envisioned, such as a bellows or an elastic coupling flector. The coupling element 30 may be axially positioned between the reduction mechanism 19 and the guiding system 24 of the low-pressure shaft 11 or, alternatively, extend beyond the reduction mechanism 19, with respect to the guiding system 24 of the low-pressure shaft 11, so that at least one radial flexibility element 301 is radially positioned inward of the fan shaft 20. In this latter case, an advantageous saving in bulk is obtained.

A balance between bulk and vibrational resistance of the reduction mechanism 19 is additionally obtained owing to the relative axial positioning of a certain number of component participating in the integration of the reduction mechanism 19. This relative axial positioning is, for example, determined during a method for manufacturing the propulsion system 1 which comprises the dimensioning of the propulsion system 1, and more precisely of the environment surrounding the reduction mechanism 19.

Since the axial positioning is relative, a reference plane P0 orthogonal to the longitudinal axis X is chosen at an axial position which is set at equal distance from the axial ends of the active part (or active parts) of the guiding system 23 of the fan shaft 20. In the scenario in which the guiding system 23 is composed of a double row of roller bearings, the plane P0 is positioned at equal distance from the two planes that each contain all the centers of the rolling elements of one of the double rows. The reference plane P0 thus determines the central position of the take-up of forces by the guiding system 23. It Is preferable to take a reference position upstream of the reduction mechanism 19 since the design of this latter is generally determined by the stiffness of the guiding system 23 of the fan shaft 20. By convention, all the elements positioned on the side of the reference plane P0 where the reduction mechanism 19 is located have a positive measurement of the distance axially separating them from the reference plane P0, whereas all the elements positioned on the side of the reference plane P0 opposite the reduction mechanism 19 have a negative measurement of the distance axially separating them from the reference plane P0.

The axial bulk of the reduction mechanism 19 compartment can thus be evaluated based on the axial position of the thrust bearing 240 which is axially nearest to the reduction mechanism 19 from among the plurality of thrust bearings of the guiding system 24 of the low-pressure shaft 11. To do this, it is advisable to determine the axial position of a first plane P1 orthogonal to the longitudinal axis X which is axially positioned at equal distance from the axial ends of the active element of the nearest thrust bearing 240. The first plane P1 thus determines the central position of the take-up of the axial forces by the nearest thrust bearing 240. The first plane P1 is axially positioned at a first distance A from the reference plane P0. The first distance A is greater than or equal to 0.4 m, preferably greater than or equal to 0.45 m, and less than or equal to 1.2 m, preferably less than or equal to 1.1 m.

The axial position of the support 19f of the reduction mechanism 19 is determined by measuring, on the one hand, the axial position of its end 191 connected to the stator part 19e of the propulsion system 1, which is axially located at a second distance B1 from the reference plane P0, and, on the other hand, the axial position of its end 192 connected to the reduction mechanism 19, which is axially located at a third distance B2 from the reference plane P0. The absolute value of the difference between the third distance B2 and the second distance B1 is representative of the axial bulk of the support 19f but also, to a certain extent, of its vibrational behavior. The second distance B1 is greater than or equal to 0.1 m, preferably greater than or equal to 0.12 m, and less than or equal to 0.5 m, preferably less than or equal to 0.4 m. The third distance B2 is greater than or equal to 0.15 m, preferably greater than or equal to 0.2 m, and less than or equal to 0.8 m, preferably less than or equal to 0.7 m.

The axial position of the reduction mechanism 19 is determined using its ring gear 19b, thanks to a second plane P2 orthogonal to the longitudinal axis X which is axially positioned at equal distance from the axial ends of the ring gear 19b. The second plane P2 is axially positioned at a fourth distance C from the reference plane P0. The fourth distance C is greater than or equal to 0.15 m, preferably greater than or equal to 0.18 m, and less than or equal to 0.5 m, preferably less than or equal to 0.4 m.

The axial bulk of the guiding system 23 of the fan shaft 20 is evaluated using a third plane P3 orthogonal à to the longitudinal axis X and axially positioned between the reference plane P0 and the reduction mechanism 19. The third P3 determines the central position of the take-up of the axial forces by the portion of the active element of the guiding system 23 of the fan shaft which extends from the reference plane P0 to the reduction mechanism 19. In the scenario where the guiding system 23 comprises rolling elements, it is in the third plane P3 that are aligned at least a part of the rolling elements of the guiding system 23 of the fan shaft 20. The third plane P3 is axially positioned at a fifth distance D from the reference plane P0. The fifth distance D is greater than or equal to 0.04 m, preferably greater than or equal to 0.045 m, and less than or equal to 0.3 m, preferably less than or equal to 0.2 m. The axial position of at least certain of the radial flexibility elements 301 of the coupling device 30 is representative both of the axial bulk of the coupling device 30, but also of the dynamic behavior of the coupling device 30 for compensating the misalignments between the low-pressure shaft 11 and the reduction mechanism 19. In this regard, a fourth plane P4 orthogonal to the longitudinal axis X is positioned at equal distance from the axial ends of the radial flexibility element 301 nearest to the guiding system 23 of the fan shaft 20 from among the plurality of radial flexibility elements 301. The fourth plane P4 is axially positioned at a sixth distance E from the reference plane, a measurement of the sixth distance E being able to be negative when the radial flexibility element 301 nearest to the guiding system 23 of the fan shaft 20 is radially positioned inward of the fan shaft 20. The sixth distance E is greater than or equal to 0.085 m, preferably greater than or equal to 0.12 m, and less than or equal to 0.7 m, preferably less than or equal to 0.6 m. Additionally, a fifth plane P5 orthogonal to the longitudinal axis X is set at equal distance from the axial ends of the radial flexibility element 301 nearest to the guiding system 24 of the low-pressure shaft 11 from among the plurality of radial flexibility elements 301. The fifth plane P5 is axially positioned at a seventh distance F from the reference plane. The seventh distance F is greater than or equal to 0.36 m, preferably greater than or equal to 0.45 m, and less than or equal to 0.9 m, preferably less than or equal to 0.85 m.

A ratio of the second distance B1 to the first distance A is greater than or equal to 0.1 and less than or equal to 0.55.

In a variant in which the fan section 2 of the propulsion system 1 is ducted, the ratio of the second distance B1 to the first distance A is greater than or equal to 0.1, preferably greater than or equal to 0.255, and less than or equal to 0.55, preferably less than or equal to 0.395.

In a variant in which the fan section 2 of the propulsion system 1 is unducted, the ratio of the second distance B1 to the first distance A is greater than or equal to 0.1, preferably greater than or equal to 0.12, and less than or equal to 0.55, preferably less than or equal to 0.35.

For example, this ratio may be obtained following the dimensioning of the propulsion system 1 during the manufacturing method.

A ratio of the third distance B2 to the first distance A is greater than or equal to 0.3, and less than or equal to 0.85.

In a variant in which the fan section 2 of the propulsion system 1 is ducted, the ratio of the third distance B2 to the first distance A is greater than or equal to 0.3, preferably greater than or equal to 0.4, and less than or equal to 0.6, preferably less than or equal to 0.55. In another variant in which the fan section 2 of the propulsion system 1 is ducted, the ratio of the third distance B2 to the first distance A is greater than or equal to 0.6 and less than or equal to 0.85.

In a variant in which the fan section 2 of the propulsion system 1 is unducted, the ratio of the third distance B2 to the first distance A is greater than or equal to 0.4 and less than or equal to 0.8.

For example, this ratio may be obtained following the dimensioning of the propulsion system 1 during the manufacturing method.

A ratio of the fourth distance C to the first distance A is greater than or equal to 0.15, and less than or equal to 0.7.

In a variant in which the fan section 2 of the propulsion system 1 is ducted, the ratio of the fourth distance C to the first distance A is greater than or equal to 0.25, preferably greater than or equal to 0.4, and less than or equal to 0.55, preferably less than or equal to 0.49.

In a variant in which the fan section 2 of the propulsion system 1 is unducted, the ratio of the fourth distance C to the first distance A is greater than or equal to 0.15 and less than or equal to 0.7, preferably less than or equal to 0.4.

For example, this ratio may be obtained following the dimensioning of the propulsion system 1 during the manufacturing method. In this manner, the compactness of the compartment housing the reduction mechanism 19 is improved and the retainment of the reduction mechanism 19 is stiffer, which improves its vibrational behavior.

A ratio of, on the one hand, a difference between the third distance B2 and the second distance B1 to, on the other hand, the fourth distance C, is greater than or equal to 1.0 and less than or equal to 1.5.

For example, this ratio may be obtained following the dimensioning of the propulsion system 1 during the manufacturing method. In this manner, when the environment surrounding the reduction mechanism 19, typically upstream, is constrained, for example by other design considerations, it is still possible to improve the vibrational behavior by adjusting the relative dimensions of the support 19f with respect to those of the reduction mechanism 19.

A ratio of the fifth distance D to the first distance A is greater than or equal to 0.04, and less than or equal to 0.39.

In a variant in which the fan section 2 of the propulsion system 1 is ducted, the ratio of the fifth distance D to the first distance A is greater than or equal to 0.1, and less than or equal to 0.39, preferably less than or equal to 0.2.

In another variant in which the fan section 2 of the propulsion system 1 is ducted, the ratio of the fifth distance D to the first distance A is greater than or equal to 0.1, preferably greater than or equal to 0.2, and less than or equal to 0.39, preferably less than or equal to 0.3.

In a variant in which the fan section 2 of the propulsion system 1 is unducted, the ratio of the fifth distance D to the first distance A is greater than or equal to 0.04 and less than or equal to 0.1.

For example, this ratio may be obtained following the dimensioning of the propulsion system during the manufacturing method.

A ratio of the sixth distance E to the first distance A is greater than or equal to −0.25, and less than or equal to 0.75.

In a variant in which the fan section 2 of the propulsion system 1 is ducted and the radial flexibility element 301 nearest to the guiding system 23 of the fan shaft 20 is radially positioned inward of the fan shaft 20, the ratio of the sixth distance E to the first distance A is greater than or equal to −0.25, preferably greater than or equal to 0, and less than or equal to 0.45, preferably less than or equal to 0.17.

In a variant in which the fan section 2 of the propulsion system 1 is ducted and the radial flexibility element 301 nearest to the guiding system 23 of the fan shaft 20 is axially positioned between the reduction mechanism 19 and the second guiding system 24, the ratio of the sixth distance E to the first distance A is greater than or equal to 0.54, preferably greater than or equal to 0.6, and less than or equal to 0.75, preferably less than or equal to 0.65.

In a variant in which the fan section 2 of the propulsion system 1 is unducted, the ratio of the sixth distance E to the first distance A is greater than or equal to 0.2 and less than or equal to 0.55. For example, this ratio may be obtained following the dimensioning of the propulsion system 1 during the manufacturing method.

A ratio of the seventh distance F to the first distance A is greater than or equal to 0.55, and less than or equal to 0.95.

In a variant in which the fan section 2 of the propulsion system 1 is ducted, the ratio of the seventh distance F to the first distance A is greater than or equal to 0.6, preferably greater than or equal to 0.65, and less than or equal to 0.95, preferably less than or equal to 0.85.

In another variant in which the fan section 2 of the propulsion system 1 is ducted, the ratio of the seventh distance F to the first distance A is greater than or equal to 0.6, preferably greater than or equal to 0.75, and less than or equal to 0.95, preferably less than or equal to 0.85.

In a variant in which the fan section 2 of the propulsion system 1 is unducted, the ratio of the seventh distance F to the first distance A is greater than or equal to 0.55 and less than or equal to 0.75.

For example, this ratio may be obtained following the dimensioning of the propulsion system 1 during the manufacturing method.

A ratio of, on the one hand, a difference between the seventh distance F and the sixth distance E to, on the other hand, the first distance A, is greater than or equal to 0.09 and less than or equal to 0.9.

In a variant in which the fan section 2 of the propulsion system 1 is ducted and the radial flexibility element 301 nearest to the guiding system 23 of the fan shaft 20 is radially positioned inward of the fan shaft 20, the ratio of, on the one hand, a difference between the seventh distance F and the sixth distance E to, on the other hand, the first distance A, is greater than or equal to 0.21, preferably greater than or equal to 0.4, and less than or equal to 0.9, preferably less than or equal to 0.7.

In a variant in which the fan section 2 of the propulsion system 1 is ducted and the radial flexibility element 301 nearest to the guiding system 23 of the fan shaft 20 is axially positioned between the reduction mechanism 19 and the second guiding system 24, the ratio of, on the one hand, a difference between the seventh distance F and the sixth distance E to, on the other hand, the first distance A, is greater than or equal to 0.09, preferably greater than or equal to 0.11, and less than or equal to 0.2, preferably less than or equal to 0.18.

In a variant in which the fan section 2 of the propulsion system 1 is unducted, the ratio of, on the one hand, a difference between the seventh distance F and the sixth distance E to, on the other hand, the first distance A, is greater than or equal to 0.1 and less than or equal to 0.25.

For example, this ratio may be obtained following the dimensioning of the propulsion system 1 during the manufacturing method.

With such values of the ratio of the sixth distance E to the first distance A, of the ratio of the seventh distance F to the first distance A, and the ratio of, on the one hand, a difference between the seventh distance F and the sixth distance E to, on the other hand, the first distance A, the compactness of the coupling device 30 is improved while maximizing its radial flexibility, and therefore its capacity to compensate for the misalignments between the low-pressure shaft 11 and the reduction mechanism 19. Hence, the reduction mechanism 19 may be less bulky and of lower mass, insofar as the reduced misalignments are less constraining on the inner components of the reduction mechanism 19.

A ratio of, on the one hand, a difference between the seventh distance F and the fourth distance C to, on the other hand, the fourth distance C, is greater than or equal to 0.3 and less than or equal to 2.0.

In a variant in which the fan section 2 of the propulsion system 1 is ducted and the radial flexibility element 301 nearest to the guiding system 23 of the fan shaft 20 is radially positioned inward of the fan shaft 20, the ratio of, on the one hand, a difference between the seventh distance F and the fourth distance C to, on the other hand, the fourth distance C, is greater than or equal to 0.3, preferably greater than or equal to 0.35, and less than or equal to 0.8, preferably less than or equal to 0.65.

In a variant in which the fan section 2 of the propulsion system 1 is ducted and the radial flexibility element 301 nearest to the guiding system 23 of the fan shaft 20 is axially positioned between the reduction mechanism 19 and the second guiding system 24, the ratio of, on the one hand, a difference between the seventh distance F and the fourth distance C to, on the other hand, the fourth distance C, is greater than or equal to 0.6, preferably greater than or equal to 0.9, and less than or equal to 1.2, preferably less than or equal to 1.1.

In a variant in which the fan section 2 of the propulsion system 1 is unducted, the ratio of, on the one hand, a difference between the seventh distance F and the fourth distance C to, on the other hand, the fourth distance C, is greater than or equal to 0.55 and less than or equal to 2.0.

For example, this ratio may be obtained following the dimensioning of the propulsion system 1 during the manufacturing method. In this way, when the environment surrounding the reduction mechanism 19 is constrained, for example by other design considerations, it is still possible to improve the vibrational behavior by adjusting the relative dimensions of the coupling device 30 with respect to those of the reduction mechanism 19.

By integrating the reduction mechanism 19 into the propulsion system 1 with the axial positioning constraints detailed in the present disclosure, an advantageous gain in the dynamic behavior of the low-pressure shaft 11 is obtained. Further, the life of the reduction mechanism 19 is increased. In addition, the misalignments between the reduction mechanism 19 and the low-pressure shaft 11 as well as the fan shaft 20 are taken up without it being necessary to over dimension the teeth of the reduction mechanism 19. This is all the more important since the more compact the reduction mechanism 19, the more its sun gear 19a is under load and therefore intolerant to misalignments.

### COMPARATIVE EXAMPLES

The table below makes it possible to compare the axial positioning of different first propulsion systems, for which the fan section 2 is ducted, for which the radial flexibility element 301 nearest to the guiding system 23 of the fan shaft 20 is axially positioned between the reduction mechanism 19 and the second guiding system 24, one being according to the present disclosure, the other being according to the technical standards at the date of filing and that the present disclosure aims to improve upon.

| | Reference | | Propulsion system | |
|---|---|---|---|---|
| | propulsion | | according to the | |
| | system | | present disclosure | |
| Thrust | 121 000N | | 121 000N | |
| Diameter D | 2 235 | mm | 2 235 | mm |
| Bypass ratio | 13 | | 13 | |
| Redline speed of the rotor 9 | 3 040 revolutions | | 3 040 revolutions | |
| of the fan section 2 | per minute | | per minute | |
| Type of reduction | planetary | | planetary | |
| mechanism 19 | | | | |
| Reduction ratio of the | 3.28 | | 3.28 | |
| reduction mechanism 19 | | | | |
| A | 547 | mm | 547 | mm |
| B1 | 100 | mm | 290 | mm |
| B2 | 120 | mm | 350 | mm |
| C | 135 | mm | 269 | mm |
| D | 50 | mm | 140 | mm |
| E | 243 | mm | 377 | mm |
| F | 305 | mm | 439 | mm |

| | | |
|---|---|---|
| Ratio of the second | 0.18 | 0.53 |
| distance B1 to the first | | |
| distance A | | |
| Ratio of the third distance | 0.22 | 0.64 |
| B2 to the first distance A | | |
| Ratio of the fourth distance | 0.25 | 0.49 |
| C to the first distance A | | |
| Ratio of the fifth distance D | 0.09 | 0.26 |
| to the first distance A | | |
| Ratio of the sixth distance E | 0.44 | 0.69 |
| to the first distance A | | |
| Ratio of the seventh | 0.56 | 0.8 |
| distance F to the first | | |
| distance A | | |
| Ratio of a difference | 0.11 | 0.11 |
| between the seventh | | |
| distance F and the sixth | | |
| distance E, to the first | | |
| distance A | | |
| Ratio of a difference | 0.15 | 0.22 |
| between the third distance | | |
| B2 and the second distance | | |
| B1, to the fourth distance C | | |
| Ratio of a difference | 1.26 | 0.63 |
| between the seventh | | |
| distance F and the fourth | | |
| distance C, to the fourth | | |
| distance C | | |

The table below makes it possible to compare the axial positioning of different second propulsion systems, for which the fan section 2 is ducted, for which the radial flexibility element 301 nearest to the guiding system 23 of the fan shaft 20 is axially positioned between the reduction mechanism 19 and the second guiding system 24, one being according to the present disclosure, the other being according to the technical standards at the date of filing and that the present disclosure aims to improve upon.

| | Reference | | Propulsion system | |
|---|---|---|---|---|
| | propulsion | | according to the | |
| | system | | present disclosure | |
| Thrust | 121 000N | | 121 000N | |
| Diameter D | 2 235 | mm | 2 235 | mm |
| Bypass ratio | 13 | | 13 | |
| Redline speed of the rotor 9 | 3 040 revolutions | | 3 040 revolutions | |
| of the fan section 2 | per minute | | per minute | |
| Type of reduction | planetary | | planetary | |
| mechanism 19 | | | | |
| Reduction ratio of the | 3.28 | | 3.28 | |
| reduction mechanism 19 | | | | |
| A | 547 | mm | 547 | mm |
| B1 | 100 | mm | 173 | mm |
| B2 | 120 | mm | 241 | mm |
| C | 135 | mm | 269 | mm |
| D | 50 | mm | 140 | mm |
| E | 243 | mm | 377 | mm |
| F | 305 | mm | 439 | mm |

| | | |
|---|---|---|
| Ratio of the second | 0.18 | 0.32 |
| distance B1 to the first | | |
| distance A | | |
| Ratio of the third distance | 0.22 | 0.44 |
| B2 to the first distance A | | |
| Ratio of the fourth distance | 0.25 | 0.49 |
| C to the first distance A | | |
| Ratio of the fifth distance D | 0.09 | 0.26 |
| to the first distance A | | |
| Ratio of the sixth distance E | 0.44 | 0.69 |
| to the first distance A | | |
| Ratio of the seventh | 0.56 | 0.80 |
| distance F to the first | | |
| distance A | | |
| Ratio of a difference | 0.11 | 0.11 |
| between the seventh | | |
| distance F and the sixth | | |
| distance E, to the first | | |
| distance A | | |
| Ratio of a difference | 0.15 | 0.25 |
| between the third distance | | |
| B2 and the second distance | | |
| B1, to the fourth distance C | | |
| Ratio of a difference | 1.26 | 0.63 |
| between the seventh | | |
| distance F and the fourth | | |
| distance C, to the fourth | | |
| distance C | | |

The table below makes it possible to compare the axial positioning of different propulsion systems, for which the fan section 2 is ducted, for which the radial flexibility element 301 nearest to the guiding system 23 of the fan shaft 20 is radially positioned inward of the fan shaft 20, one being according to the present disclosure, the other being according to the technical standards at the date of filing and that the present disclosure aims to improve upon.

| | Reference | | Propulsion system | |
|---|---|---|---|---|
| | propulsion | | according to the | |
| | system | | present disclosure | |
| Thrust | 121 000N | | 121 000N | |
| Diameter D | 2 235 | mm | 2 235 | mm |
| Bypass ratio | 13 | | 13 | |
| Redline speed of the rotor 9 | 3 040 revolutions | | 3 040 revolutions | |
| of the fan section 2 | per minute | | per minute | |
| Type of reduction | planetary | | planetary | |
| mechanism 19 | | | | |
| Reduction ratio of the | 3.28 | | 3.28 | |
| reduction mechanism 19 | | | | |
| A | 547 | mm | 547 | mm |
| B1 | 100 | mm | 173 | mm |
| B2 | 120 | mm | 241 | mm |
| C | 135 | mm | 269 | mm |
| D | 50 | mm | 140 | mm |
| E | 243 | mm | 88 | mm |
| F | 305 | mm | 364 | mm |

| | | |
|---|---|---|
| Ratio of the second | 0.18 | 0.32 |
| distance B1 to the first | | |
| distance A | | |
| Ratio of the third distance | 0.22 | 0.44 |
| B2 to the first distance A | | |
| Ratio of the fourth distance | 0.25 | 0.49 |
| C to the first distance A | | |
| Ratio of the fifth distance D | 0.09 | 0.26 |
| to the first distance A | | |
| Ratio of the sixth distance E | 0.44 | 0.16 |
| to the first distance A | | |
| Ratio of the seventh | 0.56 | 0.67 |
| distance F to the first | | |
| distance A | | |
| Ratio of a difference | 0.11 | 0.50 |
| between the seventh | | |
| distance F and the sixth | | |
| distance E, to the first | | |
| distance A | | |
| Ratio of a difference | 0.15 | 0.25 |
| between the third distance | | |
| B2 and the second distance | | |
| B1, to the fourth distance C | | |
| Ratio of a difference | 1.26 | 0.35 |
| between the seventh | | |
| distance F and the fourth | | |
| distance C, to the fourth | | |
| distance C | | |

The table below makes it possible to compare the axial positioning of different propulsion systems for which the fan section 2 is unducted, one being according to the present disclosure, the other being according to the technical standards at the date of filing and that the present disclosure aims to improve upon.

| | Reference | | Propulsion system | |
|---|---|---|---|---|
| | propulsion | | according to the | |
| | system | | present disclosure | |
| Thrust | 105 000N | | 105 000N | |
| Diameter D | 3 810 | mm | 3 810 | mm |
| Bypass ratio | 40 | | 40 | |
| Redline speed of the rotor 9 | 1 216 revolutions | | 1 216 revolutions | |
| of the fan section 2 | per minute | | per minute | |
| Type of reduction | two-stage | | two-stage | |
| mechanism 19 | | | | |
| Reduction ratio of the | 9.82 | | 9.82 | |
| reduction mechanism 19 | | | | |
| A | 1 020 | mm | 1 020 | mm |
| B1 | 210 | mm | 150 | mm |
| B2 | 490 | mm | 510 | mm |
| C | 275 | mm | 350 | mm |
| D | 100 | mm | 100 | mm |
| E | 570 | mm | 550 | mm |
| F | 850 | mm | 680 | mm |

| | | |
|---|---|---|
| Ratio of the second | 0.21 | 0.15 |
| distance B1 to the first | | |
| distance A | | |
| Ratio of the third distance | 0.48 | 0.50 |
| B2 to the first distance A | | |
| Ratio of the fourth distance | 0.27 | 0.34 |
| C to the first distance A | | |
| Ratio of the fifth distance D | 0.10 | 0.10 |
| to the first distance A | | |
| Ratio of the sixth distance E | 0.56 | 0.54 |
| to the first distance A | | |
| Ratio of the seventh | 0.83 | 0.67 |
| distance F to the first | | |
| distance A | | |
| Ratio of a difference | 0.27 | 0.13 |
| between the seventh | | |
| distance F and the sixth | | |
| distance E, to the first | | |
| distance A | | |
| Ratio of a difference | 1.02 | 1.03 |
| between the third distance | | |
| B2 and the second distance | | |
| B1, to the fourth distance C | | |
| Ratio of a difference | 2.09 | 0.94 |
| between the seventh | | |
| distance F and the fourth | | |
| distance C, to the fourth | | |
| distance C | | |

1. An aeronautical propulsion system comprising:
a stator;
a fan section comprising a fan shaft extending along a longitudinal axis, the fan section being ducted;
a first guiding system supporting and rotationally guiding the fan shaft, the first guiding system comprising a fixed part which is fixed with respect to the stator and an active part configured to transmit a force between the fan shaft and the fixed part;
a drive shaft extending along the longitudinal axis and configured to be driven by a turbine of the aeronautical propulsion system;
a second guiding system supporting and rotationally guiding the drive shaft;
a reduction structure coupling the drive shaft to the fan shaft such that a rotation of the drive shaft at a first speed drives a rotation of the fan shaft at a second speed which is less than the first speed;
a support attaching the reduction structure to the stator; and
a coupling device connecting the drive shaft to the reduction structure and configured to compensate for a misalignment between the drive shaft and the reduction structure, the coupling device comprising a plurality of shaft sections and a plurality of radial flexibility elements, each of the plurality of shaft sections extending along the longitudinal axis, each of the plurality of radial flexibility elements connecting two of the plurality of shaft sections to one another and being configured to compensate for a misalignment between the two of the plurality of shaft sections;
wherein the active part of the first guiding system has a first axial end and a second axial end, a reference plane orthogonal to the longitudinal axis being axially positioned at equal distance from the first axial end and from the second axial end of the active part of the first guiding system;
wherein the second guiding system comprises a plurality of thrust bearings, a first thrust bearing of the plurality of thrust bearings being axially positioned nearer to the reduction structure than the others of the plurality of thrust bearings, the first thrust bearing comprising a fixed part which is fixed with respect to the stator and an active part configured to transmit a force between the drive shaft and the fixed part, the active part of the first thrust bearing having a first axial end and a second axial end, a first plane orthogonal to the longitudinal axis being axially positioned at equal distance from the first axial end and from the second axial end of the active part of the first thrust bearing, the first plane being further axially positioned at a first distance from the reference plane;
wherein the support has a first end connected to the stator and a second end connected to the reduction structure, the first end of the support being axially positioned at a second distance from the reference plane and the second end of the support being axially positioned at a third distance from the reference plane;
wherein the reduction structure is an epicyclic gear train comprising a ring gear having a first axial end and a second axial end, a second plane orthogonal to the longitudinal axis being axially positioned at equal distance from the first axial end and from the second axial end of the ring gear, the second plane being further axially positioned at a fourth distance from the reference plane;
wherein the first guiding system comprises a plurality of rolling elements aligned in a third plane orthogonal to the longitudinal axis, the third plane being axially positioned between the reference plane and the reduction structure, the third plane being further axially positioned at a fifth distance from the reference plane;
wherein a first radial flexibility element of the plurality of radial flexibility elements of the coupling device is positioned nearer to the first guiding system than the others of the plurality of radial flexibility elements, the first radial flexibility element comprising a first axial end and a second axial end, a fourth plane orthogonal to the longitudinal axis being axially positioned at equal distance from the first axial end and from the second axial end of the first radial flexibility element, the fourth plane being further axially positioned at a sixth distance from the reference plane;
wherein a second radial flexibility element of the plurality of radial flexibility elements of the coupling device is positioned nearer to the second guiding system than the others of the plurality of radial flexibility elements, the second radial flexibility element having a first axial end and a second axial end, a fifth plane orthogonal to the longitudinal axis being axially positioned at equal distance from the first axial end and from the second axial end of the second radial flexibility element, the fifth plane being further axially positioned at a seventh axial distance from the reference plane;
wherein a ratio of the second distance to the first distance is greater than or equal to 0.1;
wherein a ratio of the third distance to the first distance is greater than or equal to 0.6 and less than or equal to 0.85;
wherein a ratio of the fourth distance to the first distance is greater than or equal to 0.25;
wherein a ratio of the fifth distance to the first distance is greater than or equal to 0.1;
wherein a ratio of the sixth distance to the first distance is greater than or equal to 0.54;
wherein a ratio of the seventh distance to the first distance is greater than or equal to 0.6;
wherein a ratio of a difference between the seventh distance and the sixth distance to the first distance, is greater than or equal to 0.09 and less than or equal to 0.2; and
wherein a ratio of a difference between the seventh distance and the fourth distance to the fourth distance, is greater than or equal to 0.6 and less than or equal to 1.2.

2. The aeronautical propulsion system of claim 1, wherein the first radial flexibility element is further axially positioned between the reduction structure and the second guiding system.

3. An aircraft comprising an airframe and the aeronautical propulsion system according to claim 1, wherein the aeronautical propulsion system is attached to the airframe.

4. A method of manufacturing an aeronautical propulsion system comprising:
a stator;
a fan section comprising a fan shaft extending along a longitudinal axis, the fan section being ducted;
a first guiding system supporting and rotationally guiding the fan shaft, the first guiding system comprising a fixed part which is fixed with respect to the stator and an active part configured to transmit a force between the fan shaft and the fixed part;
a drive shaft extending along the longitudinal axis and configured to be driven by a turbine of the aeronautical propulsion system;
a second guiding system supporting and rotationally guiding the drive shaft;
a reduction structure coupling the drive shaft to the fan shaft such that a rotation of the drive shaft at a first speed drives a rotation of the fan shaft at a second speed which is less than the first speed;
a support attaching the reduction structure to the stator; and
a coupling device connecting the drive shaft to the reduction structure and configured to compensate for a misalignment between the drive shaft and the reduction structure, the coupling device comprising a plurality of shaft sections and a plurality of radial flexibility elements, each of the plurality of shaft sections extending along the longitudinal axis, each of the plurality of radial flexibility elements connecting two of the plurality of shaft sections to one another and being configured to compensate for a misalignment between the two of the plurality of shaft sections;
wherein the active part of the first guiding system has a first axial end and a second axial end, a reference plane orthogonal to the longitudinal axis being axially positioned at equal distance from the first axial end and from the second axial end of the active part of the first guiding system;
wherein the second guiding system comprises a plurality of thrust bearings, a first thrust bearing of the plurality of thrust bearings being axially positioned nearer to the reduction structure than the others of the plurality of thrust bearings, the first thrust bearing comprising a fixed part which is fixed with respect to the stator and an active part configured to transmit a force between the drive shaft and the fixed part, the active part of the first thrust bearing having a first axial end and a second axial end, a first plane orthogonal to the longitudinal axis being axially positioned at equal distance from the first axial end and from the second axial end of the active part of the first thrust bearing, the first plane being further axially positioned at a first distance from the reference plane;
wherein the support has a first end connected to the stator and a second end connected to the reduction structure, the first end of the support being axially positioned at a second distance from the reference plane and the second end of the support being axially positioned at a third distance from the reference plane;
wherein the reduction structure is an epicyclic gear train comprising a ring gear having a first axial end and a second axial end, a second plane orthogonal to the longitudinal axis being axially positioned at equal distance from the first axial end and from the second axial end of the ring gear, the second plane being further axially positioned at a fourth distance from the reference plane;
wherein the first guiding system comprises a plurality of rolling elements aligned in a third plane orthogonal to the longitudinal axis, the third plane being axially positioned between the reference plane and the reduction structure, the third plane being further axially positioned at a fifth distance from the reference plane;
wherein a first radial flexibility element of the plurality of radial flexibility elements of the coupling device is positioned nearer to the first guiding system than the others of the plurality of radial flexibility elements, the first radial flexibility element comprising a first axial end and a second axial end, a fourth plane orthogonal to the longitudinal axis being axially positioned at equal distance from the first axial end and from the second axial end of the first radial flexibility element, the fourth plane being further axially positioned at a sixth distance from the reference plane;
wherein a second radial flexibility element of the plurality of radial flexibility elements of the coupling device is positioned nearer to the second guiding system than the others of the plurality of radial flexibility elements, the second radial flexibility element having a first axial end and a second axial end, a fifth plane orthogonal to the longitudinal axis being axially positioned at equal distance from the first axial end and from the second axial end of the second radial flexibility element, the fifth plane being further axially positioned at a seventh axial distance from the reference plane;
wherein the method comprises dimensioning the aeronautical propulsion system, and
wherein:
a ratio of the second distance to the first distance is determined to be greater than or equal to 0.1 and less than or equal to 0.55;
a ratio of the third distance to the first distance is determined to be greater than or equal to 0.6 and less than or equal to 0.85;
a ratio of the fourth distance to the first distance is determined to be greater than or equal to 0.25 and less than or equal to 0.55;
a ratio of the fifth distance to the first distance is determined to be greater than or equal to 0.1 and less than or equal to 0.39;
a ratio of the sixth distance to the first distance is determined to be greater than or equal to 0.54 and less than or equal to 0.75;
a ratio of the seventh distance to the first distance is determined to be greater than or equal to 0.6 and less than or equal to 0.95;
a ratio of a difference between the seventh distance and the sixth distance to the first distance is determined to be greater than or equal to 0.09 and less than or equal to 0.2; and
a ratio of a difference between the seventh distance and the fourth distance to the fourth distance is determined to be greater than or equal to 0.6 and less than or equal to 1.2.

5. The aeronautical propulsion system of claim 1, wherein the ratio of the second distance to the first distance is greater than or equal to 0.255, and less than or equal to 0.55.

6. The aeronautical propulsion system of claim 5, wherein the ratio of the second distance to the first distance is, preferably less than or equal to 0.395.

7. The aeronautical propulsion system of claim 1, wherein the ratio of the fourth distance to the first distance is greater than or equal to 0.4 and less than or equal to 0.55.

8. The aeronautical propulsion system of claim 7, wherein the ratio of the fourth distance to the first distance is less than or equal to 0.49.

9. The aeronautical propulsion system of claim 1, wherein the ratio of the fifth distance to the first distance is greater than or equal to 0.2 and less than or equal to 0.39.

10. The aeronautical propulsion system of claim 9, wherein the ratio of the fifth distance to the first distance is less than or equal to 0.3.

11. The aeronautical propulsion system of claim 1, wherein the ratio of the sixth distance to the first distance is greater than or equal to 0.6 and less than or equal to 0.75.

12. The aeronautical propulsion system of claim 11, wherein the ratio of the sixth distance to the first distance is less than or equal to 0.65.

13. The aeronautical propulsion system of claim 1, wherein the ratio of the seventh distance to the first distance is greater than or equal to 0.75 and less than or equal to 0.95.

14. The aeronautical propulsion system of claim 13, wherein the ratio of the seventh distance to the first distance is less than or equal to 0.85.

15. The aeronautical propulsion system of claim 1, wherein the ratio of the difference between the seventh distance and the sixth distance to the first distance is greater than or equal to 0.11 and less than or equal to 0.18.

16. The aeronautical propulsion system of claim 1, wherein the ratio of the difference between the seventh distance and the fourth distance to the fourth distance is greater than or equal to 0.9 and less than or equal to 1.1.
